(19) United States
(12) Patent Application Publication
(10) Pub. No.: US 2016/0035927 A1
(43) Pub. Date: Feb. 4, 2016

(54) Tandem Kesterite-Perovskite Photovoltaic Device

(71) Applicant: International Business Machines Corporation, Armonk, NY (US)

(72) Inventors: Talia S. Gershon, White Plains, NY (US); Supratik Guha, Chappaqua, NY (US); Oki Gunawan, Fair Lawn, NJ (US); Ning Li, White Plains, NY (US); Teodor K. Todorov, Yorktown Heights, NY (US)

(21) Appl. No.: 14/449,486

(22) Filed: Aug. 1, 2014

(51) Int. Cl. H01L 31/0725; H01L 51/44; H01L 31/074; H01L 51/00; H01L 31/032; H01L 31/0224; H01L 31/18; H01L 51/42; H01L 31/0296

(52) U.S. Cl. CPC H01L 31/0725; H01L 51/4273; H01L 51/442; H01L 31/074; H01L 31/0296; H01L 31/0326; H01L 31/022425; H01L 31/022475; H01L 31/18; H01L 51/4213; H01L 51/0043; H01L 51/0067; H01L 2031/0344

(57) ABSTRACT

Tandem Kesterite-perovskite photovoltaic devices and techniques for formation thereof are provided. In one aspect, a tandem photovoltaic device is provided. The tandem photovoltaic device includes a bottom cell having a first absorber layer comprising copper, zinc, tin, and at least one of sulfur and selenium and a top cell connected in series with the bottom cell, the top cell having a second absorber layer comprising a perovskite material. A method of forming a tandem photovoltaic device is also provided.

### FIELD OF THE INVENTION

The present invention relates to tandem photovoltaic devices and more particularly, to tandem Kesterite (e.g., CZT(S,Se))-perovskite photovoltaic devices and techniques for formation thereof.

### BACKGROUND OF THE INVENTION

Tandem photovoltaic devices, i.e., multi-junction solar cells based on at least two absorbers with different band gaps, allow broader-spectrum light harvesting and superior photovoltaic conversion efficiency in comparison to single-junction solar cells. Typical configurations include the layers of the tandem device oriented in a stack. For optimal performance, the band gap of the top solar cell absorber in the stack should be higher than that of the bottom cell.

The two most commonly employed groups of tandem device are: (1) two-terminal devices (i.e., those containing one electrode on top and one electrode on bottom, with a tunnel junction between top and bottom cells) and (2) four-terminal devices (i.e., those containing independent devices, each with its own top and bottom electrodes, stacked on top of each other). Three-terminal tandem devices have also been demonstrated (i.e., those having a top cell and a bottom cell which share an electrode in the middle) but this configuration is not often used in practice. Two-terminal tandem devices are more challenging to fabricate than four-terminal devices due to current-matching requirements as well as the need to preserve the performance of the bottom cell during processing of the top cell. Four-terminal tandem devices have less strict processing and current matching requirements than two-terminal devices, but suffer from significant resistance and optical losses due to the need for multiple transparent conductive contacts and reflection losses associated with adding additional substrates and layers.

Chalcogenide solar cells such as copper indium gallium selenide (CIGS) and copper zinc tin sulfo-selenide (CZT(S,Se)) have achieved their highest efficiency at relatively low band gap (approximately 1.15 electron volts (eV)). High-performance chalcogenide absorber layers also require processing temperatures above 450 degrees Celsius (° C.) for maximum performance. Therefore, chalcogenide solar cells cannot be employed as a top cell in a tandem structure due to their low band gaps and the fact that most conventional solar cell devices would deteriorate at the processing temperatures required for forming high-performance absorber materials.

CZT(S,Se)-based photovoltaic devices have been the subject of great interest for over a decade due to the fact that the materials are earth-abundant and thus deployment of CZT(S,Se) photovoltaic devices would not be limited by material availability. Cell efficiencies have reached 12.6 percent (%). See, for example, W. Wang et al., “Device Characteristics of CZTSSe Thin-Film Solar Cells with 12.6% Efficiency,” Advanced Energy Materials, vol. 4, issue 7 (November 2013). However, these devices typically suffer from low open-circuit voltage (Voc) values.

A new generation of low-cost materials based on methylammonium metal (lead (Pb), tin (Sn)) halide (iodide, chloride, bromide) perovskites have emerged in recent years with efficiencies reaching over 15%. See, for example, M. Liu et al., “Efficient planar heterojunction perovskite solar cells by vapour deposition,” Nature vol. 501, 395-398 (September 2013). These perovskite materials have large band gaps (1.5 eV to 2 eV). See, for example, A. Kojima et al., “Organometal Halide Perovskites as Visible-Light Sensitizers for Photovoltaic Cells,” Journal of the American Chemical Society, vol. 131, pp. 6050-6051, (April 2009). Having a large band gap makes perovskite materials ideally suited as a top cell in a tandem device.

While R.F. Service et al., “Perovskite Solar Cells Keep On Surging,” Science 344, no, 6183, p. 458 (May 2014) reports that a CIGS-perovskite tandem device has been demonstrated, its efficiency was just 1.5% better than the original CIGS device. Furthermore, CIGS materials include rare indium metal.

Thus, improved tandem photovoltaic device designs are needed.

### SUMMARY OF THE INVENTION

The present invention provides tandem Kesterite-perovskite photovoltaic devices and techniques for formation thereof. In one aspect of the invention, a tandem photovoltaic device is provided. The tandem photovoltaic device includes a bottom cell having a first absorber layer including copper, zinc, tin, and at least one of sulfur and selenium; and a top cell connected in series with the bottom cell, the top cell having a second absorber layer including a perovskite material.

In another aspect of the invention, another tandem photovoltaic device is provided. The tandem photovoltaic device includes a substrate; a layer of electrically conductive material on the substrate; a first absorber layer on a side of the layer of electrically conductive material opposite the substrate, wherein the first absorber layer includes copper, zinc, tin, and at least one of sulfur and selenium; a buffer layer on a side of the first absorber layer opposite the layer of electrically conductive material; a transparent front contact on a side of the buffer layer opposite the first absorber layer; a hole transporting layer on a side of the transparent front contact opposite the buffer layer; a second absorber layer on a side of the hole transporting layer opposite the transparent front contact, wherein the second absorber layer includes a perovskite material; an electron transporting layer on a side of the second absorber layer opposite the hole transporting layer; and a transparent top electrode on a side of the electron transporting layer opposite the second absorber layer.

In yet another aspect of the invention, a method of forming a tandem photovoltaic device is provided. The method includes the steps of: coating a substrate with a layer of electrically conductive material; forming a first absorber layer on a side of the layer of electrically conductive material opposite the substrate, wherein the first absorber layer includes copper, zinc, tin, and at least one of sulfur and selenium; forming a buffer layer on a side of the first absorber layer opposite the layer of electrically conductive material; forming a transparent front contact on a side of the buffer layer opposite the first absorber layer; forming a hole transporting layer on a side of the transparent front contact opposite the buffer layer; forming a second absorber layer on a side of the hole transporting layer opposite the transparent front contact, wherein the second absorber layer includes a perovskite material; forming an electron transporting layer on a side of the second absorber layer opposite the hole transporting layer; and forming a transparent top electrode on a side of the electron transporting layer opposite the second absorber layer.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary two-terminal, two-cell tandem photovoltaic device according to an embodiment of the present invention;

FIG. 2 is a diagram illustrating an exemplary methodology for forming a two-terminal, two-cell tandem photovoltaic device according to an embodiment of the present invention;

FIG. 3 is a diagram illustrating a cross-sectional scanning electron microscope (SEM) image of a two-cell tandem photovoltaic device formed according to the present techniques according to an embodiment of the present invention;

FIG. 4A is a diagram illustrating current voltage (J-V) curves of a stand-alone baseline CZT(S,Se) device and a stand-alone baseline perovskite device according to an embodiment of the present invention;

FIG. 4B is a diagram illustrating J-V curves for the tandem photovoltaic device of FIG. 3 at 1 sun and at 3.8 suns according to an embodiment of the present invention;

FIG. 5A is an image illustrating band gap tuning in perovskite samples by varying the halide concentration which brings about a color evolution from dark to light as chlorine and bromine are added to pure-iodide perovskite according to an embodiment of the present invention; and

FIG. 5B is a diagram illustrating transmission spectra for the perovskite samples in FIG. 5A according to an embodiment of the present invention.

### DETAILED DESCRIPTION OF PREFERRED EMBODIMENTS

A tandem, i.e., multi-junction, photovoltaic device architecture allows the combined two-cell stack to achieve high open-circuit voltages (Voc) reaching a maximum value of the sum of the two individual cell voltages. The total short-circuit current density produced by the tandem device is limited by whichever of the individual cells produces the lower current density.

Provided herein is a two-terminal, two-cell tandem photovoltaic device having a copper zinc tin sulfo-selenide (CZT(S,Se))-based bottom cell and a perovskite-based top cell. It is shown in accordance with the present techniques that the open-circuit voltage of the present tandem device is indeed larger than either of the individual cells and approaches the sum of the two individual Voc values, thereby demonstrating the tandem concept.

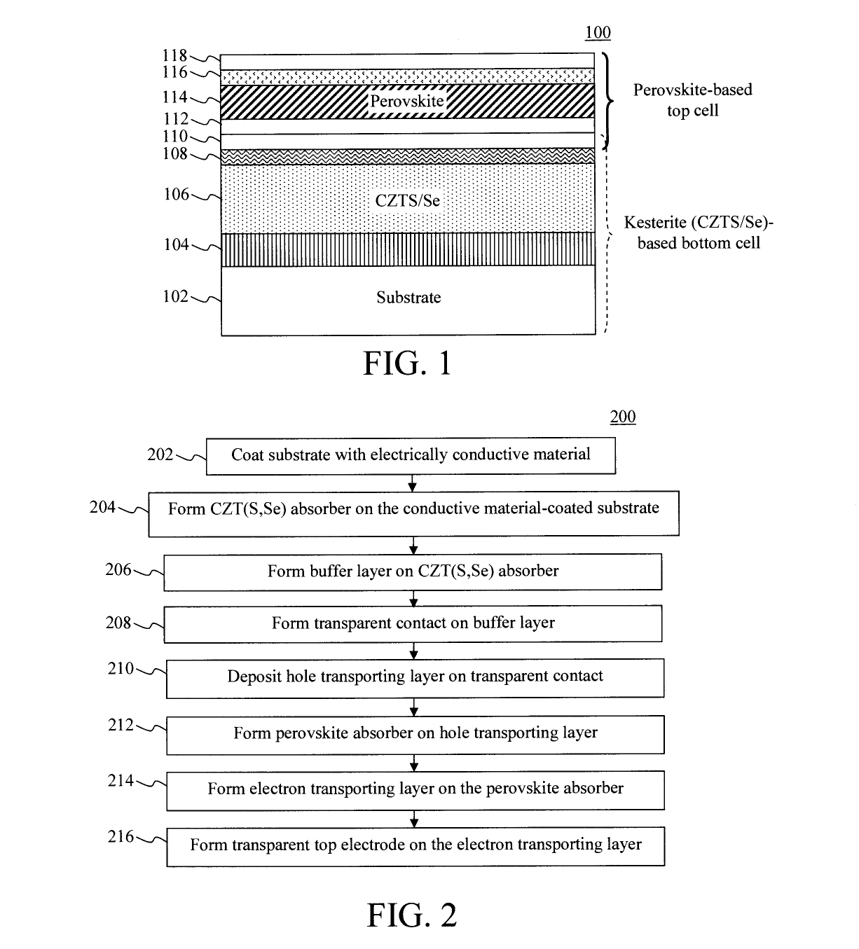

FIG. 1 is a diagram illustrating an exemplary two-terminal, two-cell tandem photovoltaic device 100 according to the present techniques. As shown in FIG. 1, the device 100 includes two cells, a Kesterite (CZT(S,Se))-based bottom cell (i.e., the absorber in the bottom cell is CZT(S,Se)), and a perovskite-based top cell (i.e., the absorber in the top cell is a perovskite material).

As its name implies, a CZT(S,Se) material contains common, readily available elements namely copper (Cu), zinc (Zn), tin (Sn), and at least one of sulfur (S) and selenium (Se). For a general discussion on Kesterite and use of Kesterite in solar cells, see, for example, Mitzi et al., “Prospects and performance limitations for Cu—Zn—Sn—S—Se photovoltaic technology,” Phil Trans R Soc A 371 (July 2013), the contents of which are incorporated by reference as if fully set forth herein.

The term “perovskite” refers to materials with a perovskite structure and the general formula ABX₃ (e.g., wherein A=CH₃NH₃ or NH═CHNH₃, B=lead (Pb) or tin (Sn), and X=chlorine (Cl) or bromine (Br) or iodine (I)). The perovskite structure is described and depicted, for example, in U.S. Pat. No. 6,429,318 B1 issued to Mitzi, entitled “Layered Organic-Inorganic Perovskites Having Metal-Deficient Inorganic Frameworks” (hereinafter “Mitzi”), the contents of which are incorporated by reference as if fully set forth herein. As described in Mitzi, perovskites generally have an ABX₃ structure with a three-dimensional network of corner-sharing BX₆ octahedra, wherein the B component is a metal cation that can adopt an octahedral coordination of X anions, and the A component is a cation located in the 12-fold coordinated holes between the BX₆ octahedra. The A component can be an organic or inorganic cation. See, for example, FIGS. 1a and 1b of Mitzi.

Specifically, as shown in FIG. 1 the kesterite (CZT(S,Se))-based bottom cell has a substrate 102 coated with a layer 104 (or optionally multiple layers represented generally by layer 104) of an electrically conductive material, a CZT(S,Se) absorber layer 106 on a side of the conductive layer 104 opposite the substrate 102, a buffer layer 108 on a side of the CZT(S,Se) absorber layer 106 opposite the conductive layer 104, and a transparent front contact 110 on a side of the buffer layer 108 opposite the CZT(S,Se) absorber layer 106.

Suitable substrates include, but are not limited to, glass, ceramic, metal foil, or plastic substrates. Suitable materials for forming conductive layer 104 include, but are not limited to, molybdenum (Mo), nickel (Ni), tantalum (Ta), tungsten (W), aluminum (Al), platinum (Pt), titanium nitride (TiN), silicon nitride (SiN), and combinations including at least one of the foregoing materials (for example as an alloy of one or more of these metals or as a stack of multiple layers). According to an exemplary embodiment, the conductive layer 104 is coated on substrate 102 to a thickness of greater than about 0.1 micrometers (μm), e.g., from about 0.1 μm to about 2.5 μm, and ranges therebetween. Conductive layer 104 will serve as the bottom electrode of the (i.e., two-terminal) device 100. In general, the various layers of the device 100 will be deposited sequentially using a combination of vacuum-based and/or solution-based approaches.

As highlighted above, the CZT(S,Se) absorber layer 106 contains Cu, Zn, Sn, and at least one of S and Se. Exemplary processes for forming the CZT(S,Se) absorber layer 106 will be described in detail below.

It is notable that since the top and bottom cells in the configuration shown are essentially two solar cells connected in series, the two cells must be current-matched in order to have a high-performance device. Current-matching in tandem photovoltaic device configurations is based in large part on the band gap of the absorbers in the individual cells. Advantageously, according to the present techniques the band gap of the CZT(S,Se) absorber layer 106 of the bottom cell and the band gap of the perovskite absorber layer 114 (see below) of the top cell can each be individually tuned in order to optimize the current-matching between the cells. Band gap tuning in the CZT(S,Se) absorber layer 106 can be achieved by varying the S to Se ratio. Techniques for regulating a ratio of S and Se during CZT(S,Se) formation are described, for example, in D. B. Mitzi et al., “The path towards a high-performance solution-processed kesterite solar cell,” Solar Energy materials & Solar Cells, vol. 95, issue 6, pp. 1421-1436 (June 2011) the contents of which are incorporated by reference as if fully set forth herein, and in U.S. Patent Application Publication Number 2012/0100663 filed by Bojarczuk et al., entitled “Fabrication of CuZnSn(S,Se) Thin Film Solar Cell with Valve Controlled S and Se” (hereinafter “U.S. Patent Application Publication Number 2012/0100663”) the contents of which are incorporated by reference as if fully set forth herein.

To optimize performance, in tandem photovoltaic devices the band gap of the top cell absorber should be higher than that of the bottom cell absorber. Thus, in this particular example the device 100 is configured such that the relatively higher band gap absorber material (i.e., the perovskite absorber layer 114 (see below)) is used in the top cell and the relatively lower band gap absorber material (i.e., the CZT(S,Se) absorber layer 106) is used in the bottom cell. As highlighted above, the CZT(S,Se) components are earth-abundant and have been demonstrated to have high efficiencies thus making CZT(S,Se) materials desirable for solar device fabrication. Perovskite materials have large band gaps (e.g., from about 1.5 electron volts (eV) to 3 eV, and ranges therebetween) which makes them well suited as a top cell absorber in a tandem device with low-band gap CZT(S,Se) (e.g., from about 1 eV to about 1.5 eV, and ranges therebetween).

However employing such a perovskite top cell/CZT(S,Se) bottom cell configuration presents notable production challenges. For instance, chalcogenide devices (such as CZT(S,Se) solar cells) may only be used as the bottom cell in a two-terminal tandem device when the top cell processing temperature remains below about 150° C. due to the instability of the p-n junction above this temperature. This requirement limits the kinds of devices which can be prepared on top of CZT(S,Se) in a two-terminal tandem structure. Advantageously, exemplary techniques are implemented herein for low-temperature perovskite formation (see below) to enable a perovskite absorber-based top cell to be produced over a CZT(S,Se) bottom cell without damaging the bottom cell.

According to an exemplary embodiment, the buffer layer 108 is formed from at least one of cadmium sulfide (CdS), a cadmium-zinc-sulfur material of the formula Cd₁₋ₓZnₓS (wherein 0<x≦1), indium sulfide (In₂S₃), zinc oxide, zinc oxysulfide (e.g., a Zn(O,S) or Zn(O,S,OH) material), and aluminum oxide (Al₂O₃), and has a thickness of from about 50 angstroms (Å) to about 1,000 Å, and ranges therebetween. The buffer layer 108 and the CZT(S,Se) absorber layer 106 form a p-n junction therebetween. According to an exemplary embodiment, the transparent front contact 110 is formed from a transparent conductive oxide (TCO) such as indium-tin-oxide (ITO) and/or aluminum (Al)-doped zinc oxide (ZnO) (AZO)).

The perovskite-based top cell has at its base a bottom electrode. Suitable materials for forming the bottom electrode include, but are not limited to, transparent conductive oxides such as AZO and/or ITO (e.g., the same materials present in the transparent front contact 110). Thus, in the exemplary embodiment depicted in FIG. 1, the transparent front contact 110 serves as both a top electrode of the CZT(S,Se)-based bottom cell and the bottom electrode of the perovskite-based top cell. As shown in FIG. 1, the perovskite-based top cell has a hole transporting layer 112 on a side of the transparent front contact 110 opposite the buffer layer 108, a perovskite absorber layer 114 on a side of the hole transporting layer 112 opposite the transparent front contact 110, an electron transporting layer 116 on a side of the perovskite absorber layer 114 opposite the hole transporting layer 112, and a transparent top electrode 118 on a side of the electron transporting layer 116 opposite the perovskite absorber layer 114.

According to an exemplary embodiment, the hole transporting layer 112 is formed from poly(3,4-ethylenedioxythiophene)-poly(styrenesulfonate) (PEDOT:PSS) or molybdenum trioxide (MoO₃). PEDOT:PSS and MoO₃ are used in various photovoltaic applications as hole transporting materials. As is known in the art, electron holes (or simply “holes”) represent the lack or absence of an electron. Electrons and holes are charge carriers in semiconductor materials.

An exemplary process for forming the perovskite absorber layer 114 will be described in detail below. In general however, the process involves synthesizing the perovskite from a metal halide film and a source of methylammonium halide vapor. The perovskite synthesis process may be carried out under a vacuum in order to lower processing temperatures and thereby preventing any potential damage to the underlying bottom cell (see above).

As provided above, band gap tuning of the perovskite absorber layer 114 provides another mechanism by which to optimize the current-matching between the (top and bottom) cells. Band gap tuning in the perovskite absorber layer 114 can be achieved by varying the halide concentration in the perovskite. This band gap tuning process for perovskite is described in detail below.

According to an exemplary embodiment, electron transporting layer 116 is formed from at least one of phenyl-C61-butyric acid methyl ester (PCBM), C60, and bathocuproine (BCP). PCBM, C60, and BCP are hole-blocking, electron transporting materials.

Transparent top electrode 118 will serve as the top electrode of the (e.g., two-terminal) device 100. According to an exemplary embodiment, transparent top electrode 118 is formed from a thin layer of metal (e.g., a layer of aluminum having a thickness of from about 5 nanometers (nm) to about 50 nm, and ranges therebetween), ITO, AZO, a silver nanowire mesh, or any other material which is both partially transparent in the visible spectrum and electrically conducting. Transparent electrically conductive silver nanowire films are described, for example, in Liu et al., “Silver nanowire-based transparent, flexible, and conductive thin film,” Nanoscale Research Letters, 6:75 (January 2011) (hereinafter “Liu”), the contents of which are incorporated by reference as if fully set forth herein. As shown, for example, in FIG. 2 of Liu, silver nanowires form a web-like film which is porous. The film is also transparent.

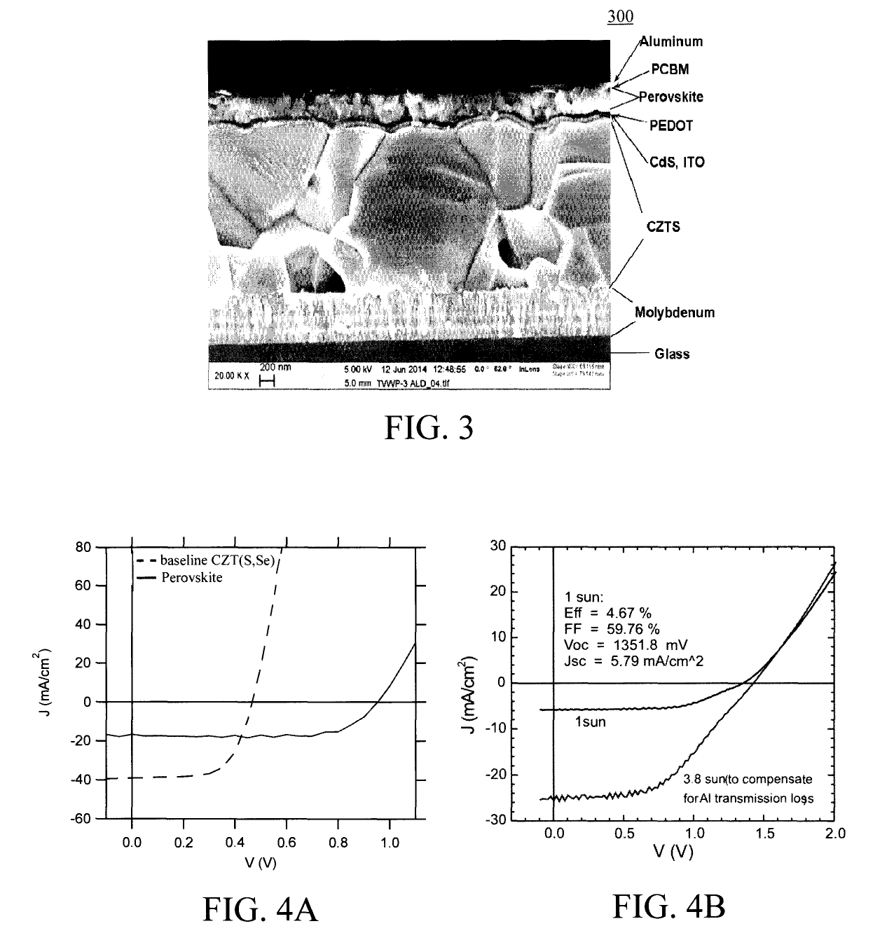

Device 100 is a two-terminal, tandem photovoltaic device. By two-terminal it means that only two electrodes of the device need to be contacted: one on top, and one on the bottom (FIG. 1, layer 104 of electrically conductive material and transparent top electrode 118, or in FIG. 3—described below—the aluminum on top and the molybdenum on the bottom). The “electrodes” in the middle which complete the CZT(S,Se) device and begin the perovskite device (e.g., ITO or AZO/PEDOT:PSS) act as a “tunnel junction,” so electrons from the bottom cell move “upwards” and recombine with holes in the bottom cell moving “downwards” (effectively what is left as current from the device is holes from the bottom cell moving “downwards” and electrons from the top cell moving “upwards”).

FIG. 2 is a diagram illustrating an exemplary methodology 200 for forming a two-terminal, two-cell tandem photovoltaic device, such as device 100 of FIG. 1. As highlighted above, according to an exemplary embodiment the device is built sequentially, layer-by-layer from the bottom up with the result being a perovskite absorber based top cell having been formed on a CZT(S/Se)-based bottom cell. In that case, the starting platform for the fabrication process is a substrate 102 which in step 202 is coated with a layer(s) of an electrically conductive material 104. As highlighted above, suitable substrates include, but are not limited to, glass, ceramic, metal foil, or plastic substrates. Suitable electrically conductive materials for layer 104 include, but are not limited to, Mo, Ni, Ta, W, Al, Pt, TiN, SiN, and combinations including at least one of the foregoing materials (for example as an alloy of one or more of these metals or as a stack of multiple layers). By way of example only, the electrically conductive material 104 can be deposited onto the substrate using evaporation or sputtering.

In step 204, the CZT(S,Se) absorber layer 106 is formed on the conductive material-coated substrate. As highlighted above, CZT(S,Se) absorber layer 106 contains Cu, Zn, Sn, and at least one of S and Se. By way of example only, CZT(S,Se) absorber layer 106 may be formed using vacuum-based, solution-based, or other suitable approaches to form a stack of layers. See for example U.S. Patent Application Publication Number 2012/0061790 filed by Ahmed et al., entitled “Structure and Method of Fabricating a CZTS Photovoltaic Device by Electrodeposition,” the contents of which are incorporated by reference as if fully set forth herein. The sequence of the layers in the stack may be configured so as to achieve optimal band grading and/or adhesion to the substrate, as is known in the art. See, for example, Dullweber et al., “Back surface band gap gradings in Cu(In,Ga)Se₂ solar cells,” Thin Solid Films, vol. 387, 11-13 (May 2001), the contents of which are incorporated by reference as if fully set forth herein. Suitable solution-based Kesterite fabrication techniques are described for example in U.S. Patent Application Publication Number 2013/0037111 filed by Mitzi et al., entitled “Process for Preparation of Elemental Chalcogen Solutions and Method of Employing Said Solutions in Preparation of Kesterite Films,” the contents of which are incorporated by reference as if fully set forth herein. A suitable particle-based precursor approach for CZT(S,Se) formation is described for example in U.S. Patent Application Publication Number 2013/0037110, filed by Mitzi et al., entitled “Particle-Based Precursor Formation Method and Photovoltaic Device Thereof,” the contents of which are incorporated by reference as if fully set forth herein.

According to an exemplary embodiment, the ratio of S to Se in the CZT(S,Se) absorber layer 106 is controlled in order to tune the band gap of the CZT(S,Se) absorber layer 106 and thereby optimize current-matching between the (top and bottom) cells. By way of example only, the techniques described in U.S. Patent Application Publication Number 2012/0100663 may be employed during formation of CZT(S,Se) absorber layer 106 to control the ratio of S to Se. For highest tandem cell efficiency, the bottom cell would have a band gap of from about 0.9 eV to about 1.05 eV (see below). This process can be used to create a CZT(S,Se) absorber composition ranging from pure sulfur to pure selenium and S/Se combinations therebetween. Pure sulfur (sulfide) gives the CZT(S,Se) absorber a band gap of about 1.5 electron volts (eV) whereas pure selenium (selenide) gives the CZT(S,Se) absorber a band gap of about 0.96 eV. Thus, to decrease the band gap of the CZT(S,Se) absorber layer 106 towards the optimized value for a tandem, one might increase the amount of selenium (relative to sulfur).

Following deposition of the CZT(S,Se) materials, as is known in the art a post anneal in a chalcogen environment is preferably performed. Namely, the as-deposited materials have poor grain structure and a lot of defects. The anneal in the chalcogen environment improves the grain structure and defect landscape in the material.

In step 206, the buffer layer 108 is formed on the CZT(S,Se) absorber layer 106. As provided above, the buffer layer 108 may be formed from at least one of CdS, a cadmium-zinc-sulfur material of the formula Cd₁₋ₓZnₓS (wherein 0<x≦1), In₂S₃, zinc oxide, zinc oxysulfide (e.g., a Zn(O,S) or Zn(O,S,OH) material), and Al₂O₃. According to an exemplary embodiment, the buffer layer 108 is formed on CZT(S,Se) absorber layer 106 using standard chemical bath deposition.

In step 208, the transparent front contact 110 is formed on the buffer layer 108. As provided above, the transparent front contact 110 may be formed from a transparent conductive oxide (TCO) such as ITO and/or AZO. According to an exemplary embodiment, the transparent front contact is formed on the buffer layer by sputtering. As provided above, the transparent front contact 110 serves as both a top electrode of the CZT(S,Se)-based bottom cell and the bottom electrode of the perovskite-based top cell. Thus, formation of the transparent front contact 110 on the buffer layer 108 completes fabrication of the CZT(S,Se)-based bottom, and is the first step in fabricating the perovskite-based top cell.

The next step in forming the perovskite-based top cell, step 210, is to deposit the hole transporting layer 112 on the transparent front contact 110. As provided above, the hole transporting layer 112 may be formed from PEDOT:PSS, MoO₃, or another hole-transporting material that makes ohmic contact to the perovskite. According to an exemplary embodiment, the hole transporting layer 112 is deposited onto the transparent front contact 110 using a spin-coating or evaporation process.

As highlighted above, in a two-terminal, tandem photovoltaic device a “tunnel junction” is needed between the top and bottom electrodes that facilitates recombination between electrons from the bottom cell and holes from the top cell. So, it is in fact the transparent front contact 110/hole transporting layer 112 (e.g., ITO or AZO/PEDOT:PSS) junction which is the tunnel junction in this case, as holes transported through the hole transporting layer 112 recombine with electrons transported through the transparent front contact 110.

In step 212, the perovskite absorber layer 114 is formed on the hole transporting layer 112. According to an exemplary embodiment, the perovskite absorber layer 114 is formed on the hole transporting layer 112 using the techniques described in U.S. patent application Ser. No. ______, given Attorney Docket Number YOR920140171US1, entitled “Techniques for Perovskite Layer Crystallization” (hereinafter “Attorney Docket Number YOR920140171US1”) the contents of which are incorporated by reference as if fully set forth herein. In general, the process involves using vacuum annealing of a metal halide (e.g., lead or tin iodide, chloride or bromide) and a methylammonium halide source (e.g., methylammonium iodide, methylammonium bromide, and methylammonium chloride) to create a methylammonium halide vapor which reacts with the metal halide to form a perovskite material. One notable advantage of the techniques presented in Attorney Docket Number YOR920140171US1 is that the annealing under a vacuum permits significantly lower reaction temperatures than those used in other processes. For instance, temperatures below 150 degrees Celsius (° C.), e.g., from about 60° to about 150° C., and ranges therebetween can be employed. As highlighted above, processing temperatures are an important consideration when building a cell on top of a CZT(S,Se) bottom cell.

Another notable advantage of the techniques presented in Attorney Docket Number YOR920140171US1 is that they optionally permit real-time monitoring of the reaction to optimize the properties of the layer based on the changing optical properties of reactants as the perovskite is being formed. Reaction and monitoring set-ups are presented therein that permit real-time transmission (in the case of transparent samples) and reflective (in the case of non-transparent samples) measurements to be made.

Yet another notable advantage of the techniques presented in Attorney Docket Number YOR920140171US1 is that they permit formation of high-quality, uniform perovskite layers over large device areas. Specifically, the methylammonium halide source may be a methylammonium halide-coated substrate placed facing and in close proximity to the metal halide during the vacuum annealing. This configuration permits uniform perovskite formation on large device substrates.

As provided above, the current-matching between the top and bottom cells can be optimized by tuning the band gap of the respective absorber materials. For instance, the S to Se ratio can be regulated to tune the band gap of the CZT(S,Se) absorber. With regard to the perovskite absorber, the band gap can be varied by varying the metal halide composition in the perovskite. For instance, in the exemplary perovskite formation process described above the starting metal halide layer (which reacts with the methylammonium vapor) has the formula MX₂, wherein M is lead (Pb) and/or tin (Sn), and X is at least one of fluorine (F), chlorine (Cl), bromine (Br), and/or iodine (I). Lead- and tin-based perovskite materials have different band gaps. For instance, the lead-free perovskite CH₃NH₃SnI₃ has a band gap of 1.23 eV while the band gap of the pure-lead perovskite CH₃NH₃PbI₃ is about 1.55 eV. Further, changing the halide composition can also affect band gap. For example, the material CH₃NH₃PbBr₃ has a band gap of about 2.25 eV. The optimum band gap for the top cell in the tandem device is about 1.7 eV for a bottom cell band gap of about 1.0 eV (e.g., pure-selenide CZTSe). This band gap could be achieved by slightly increasing the band gap of the CH₃NH₃PbI₃ via the introduction of Cl or Br. Or, alternatively, a band gap of 1.7 eV could be achieved by starting with CH₃NH₃SnI₃ and adding significantly more chlorine or bromine. See example below comparing metal halide samples containing iodide alone (pure iodide), iodide/chloride, iodide/bromide, and iodide/chloride/bromide which indicate a transition from darker to lighter as the chlorine and bromine are added to the pure-iodide perovskite; the lighter coloration of the films is due a reduction in light absorption to the larger band gap of the material.

Next in step 214, electron transporting layer 116 is formed on the perovskite absorber layer 114. As provided above, the electron transporting layer 116 may be formed from at least one of PCBM, C60, and BCP. According to an exemplary embodiment, the electron transporting layer 116 is deposited onto the perovskite absorber layer 114 using a spin-coating or evaporation process.

In step 216, the transparent top electrode 118 is formed on the electron transporting layer 116. As provided above, the transparent top electrode 118 may be formed from a thin layer of metal (e.g., aluminum (Al)), ITO, AZO, or a silver nanowire mesh. A thin aluminum layer can be formed using evaporation. ITO and AZO are often deposited using sputtering or a chemical vapor deposition (CVD)-based process. Alternatively, a layer of ITO or AZO nanoparticles could be coated from a suspension on top of the device. Silver nanowire meshes can be prepared using various solution-based processes such as spray-coating from a suspension in alcohol. Formation of the transparent top electrode 118 completes the device.

The present techniques are further described by way of reference to the following non-limiting example:

CZT(S,Se) bottom cell: CZT(S,Se) was coated onto molybdenum (Mo)-coated substrates by one of vacuum evaporation and solution-processing. Using one or both of these two approaches, CZT(S,Se) films can be prepared over a wide range of chalcogen compositions from pure selenide (giving an energy band gap (Eg) of about 0.96 electron volts (eV)) to pure sulfide (giving an Eg of about 1.5 eV). Following CZT(S,Se) deposition, the layers were briefly annealed in a chalcogen environment at a temperature of about 600° C. A buffer layer (in this example CdS) was then deposited onto the CZT(S,Se) to form a p-n junction, and then a ZnO/ITO bilayer electrode was sputtered on top to complete the bottom cell.

Perovskite top cell: A perovskite device was grown on top of the CZT(S,Se) device. The bottom electrode of the perovskite device was ITO or ZnO:Al (which completes the bottom CZT(S,Se) cell and was therefore already present). On top of this electrode, a hole-selective contact (in this example PEDOT:PSS) was deposited. The PEDOT:PSS layer was spin-coated from a commercial aqueous suspension at 3,000 revolutions per minute (rpm) and annealed at 140° C. for 10 minutes. Following deposition of the hole-selective contact, the perovskite layer was solution-processed onto the stack in accordance with the techniques provided in Attorney Docket Number YOR920140171US1. Lead iodide (PbI₂) layers were prepared by spin-coating 0.8M PbI₂ in dimethylformamide (DMF) at 2,000 rpm. The sample was placed in the reaction and monitoring apparatus described in Attorney Docket Number YOR920140171US1 in the presence of a close-spaced methylammonium iodide source and treated at 80° C. for 14 hours. It is notable that a different metal (Pb, Sn) halide (I, Cl, Br) could have been used to prepare a perovskite material with different composition and therefore a different band gap, which is one parameter that must be optimized for high efficiency (see above). An electron-selective layer (2% PCBM, 1,000 rpm) was spin-coated on top of the perovskite layer. Finally, a transparent and conductive electrode was prepared on top. In this example, the electrode was a thin layer of Al metal (sheet resistance 200-1,000 ohm square and 30-60% transmission).

FIG. 3 shows a cross-sectional scanning electron microscope (SEM) image 300 of the tandem CZT(S,Se)/perovskite structure formed in the above example. Each layer in the stack is identified on the right side of the image. As per a standard high-efficiency “baseline” process, a layer of CZT(S,Se) having a thickness of from about 1.5 micrometers (μm) to about 2 μm, and ranges therebetween, is employed in the bottom cell. A much thinner (e.g., from about 100 nm to about 500 nm, and ranges therebetween) perovskite layer is used for the top cell due to the excellent absorption properties of these materials.

A current voltage (J-V) curve of a stand-alone baseline CZT(S,Se) device (single-cell) is shown in FIG. 4A, wherein the device displays the following characteristics: open circuit voltage (Voc)=465 millivolts (mV), short circuit current density (Jsc)=38 mA/cm2, fill factor (FF)=65%, energy conversion efficiency (η)=11.5%. Voc values in these baseline CZT(S,Se) devices typically range from about 440 millivolts (mV) to about 460 mV. Overlaid with the CZT(S,Se) J-V curve is a similar measurement performed on a stand-alone perovskite, wherein the device displayed the following characteristics: Voc=953 mV, Jsc=16.8 mA/cm2, FF=76.6%, η=12.3%. Due to the larger band gap of this material, the Jsc value is smaller and the Voc is larger than the values corresponding to the CZT(S,Se) device.

FIG. 4B displays a J-V measurement of a tandem CZT(S,Se)/perovskite device (e.g., as shown in FIG. 3 and prepared in the above example) at 1 sun and at 3.8 suns. The tandem device at 1 sun displays the following characteristics: Voc=1353 mV, Jsc=5.63 mA/cm2, FF=60.35%, η=4.6%. It is notable that the Voc value of 1352 mV is nearly equal to the sum of the individual Voc values of the CZT(S,Se) and perovskite devices, thus confirming that a series-connected, two-terminal tandem device has been effectively formed. Under an illumination of 3.8 suns (meant to simulate removal of the losses associated with the poor top contact transparency), the device results become: Voc=1426 mV, Jsc=25.7 mA/cm2, FF=47%, η=17.2%. This indicates that improvements to the top contact will have significant impact on the overall conversion efficiency of the device.

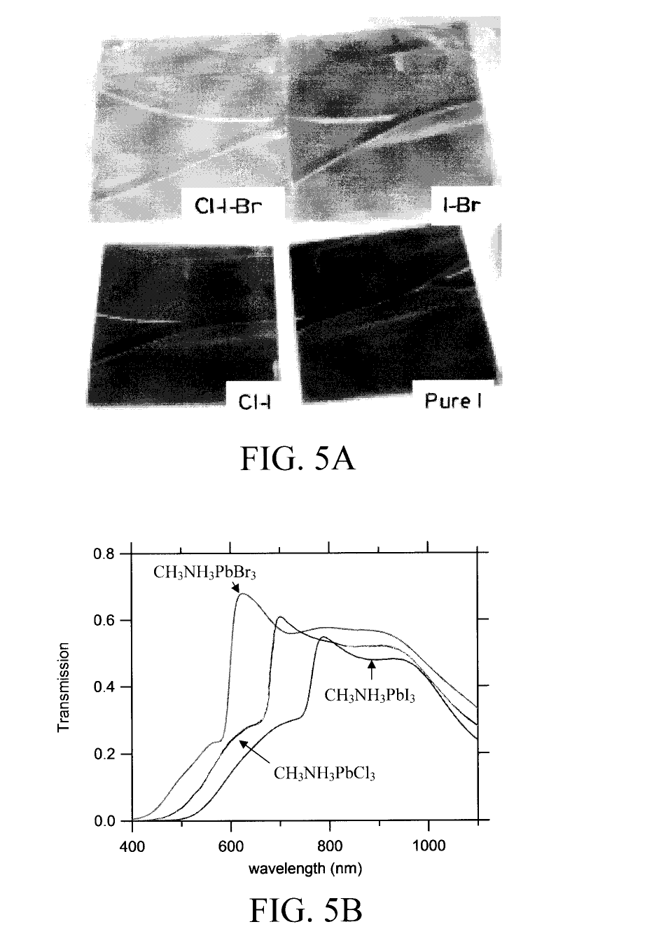

As described in detail above, optimized current-matching of the top and bottom cells will require the ability to tune the band gap of the top and/or bottom cells. FIGS. 5A and 5B show the variation in band gap that can be obtained by varying the halide concentration in the perovskite material. In FIG. 5A, the color evolution from darker to lighter can be observed as chlorine and bromine are added to the pure-iodide (Pure I) perovskite. Moving from darkest to lightest, samples with iodine, iodine and chlorine (Cl—I), iodine and bromine (I—Br), and iodine, chlorine and bromine (Cl—I—Br) are shown. As shown in FIG. 5B, the same trend can be seen in the transmission spectra, which show the ability to control the absorption onset of the semiconductor simply by changing the halide. As provided above, band gap tuning can be achieved in CZT(S,Se) by varying the sulfur to selenium ratio in the material.

A maximum cell conversion efficiency in a tandem device would be achieved with a top cell band gap of from about 1.6 eV to about 1.7 eV, and a bottom cell band gap of from about 0.9 eV to about 1.05 eV. See, for example, Christiana Honsberg and Stuart Bowden, PVCDROM, section 4.2 Solar Cell Parameters, Tandem Cells, the contents of which are incorporated by reference as if fully set forth herein (which shows the simulated maximum conversion efficiency that can be expected from a tandem cell based on absorbers with two different band gaps). Band gap tuning of the present perovskite/CZT(S,Se) cells, as described in detail above, can be used to optimize the efficiency of the present devices to achieve maximum cell conversion efficiency.

In conclusion, the present techniques provide a tandem photovoltaic device where the bottom cell contains a CZT(S,Se) absorber and the top cell contains a methylammonium metal halide perovskite absorber. By stacking these two devices in series, high open-circuit voltages approaching a value equal to the sum of the two individual cell voltages can be achieved. The short-circuit current density is limited by the smaller of the two current densities of the individual cells and by the light reaching each device. The band gaps of the two cells can each be optimized to achieve optimal current-matching for a two-terminal tandem device.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A tandem photovoltaic device, comprising:
a bottom cell having a first absorber layer comprising copper, zinc, tin, and at least one of sulfur and selenium; and
a top cell connected in series with the bottom cell, the top cell having a second absorber layer comprising a perovskite material.

2. The tandem photovoltaic device of claim 1, wherein the bottom cell further comprises:
a substrate;
a layer of electrically conductive material on the substrate, wherein the first absorber layer is present on a side of the layer of electrically conductive material opposite the substrate;
a buffer layer on a side of the first absorber layer opposite the layer of electrically conductive material; and
a transparent front contact on a side of the buffer layer opposite the first absorber layer.

3. The tandem photovoltaic device of claim 2, wherein the substrate comprises a glass, ceramic, metal foil, or plastic substrate.

4. The tandem photovoltaic device of claim 2, wherein the layer of electrically conductive material is formed from a material selected from the group consisting of molybdenum, nickel, tantalum, tungsten, aluminum, platinum, titanium nitride, silicon nitride, and combinations comprising at least one of the foregoing materials.

5. The tandem photovoltaic device of claim 2, wherein the buffer layer comprises at least one of cadmium sulfide, a cadmium-zinc-sulfur material, indium sulfide, zinc oxide, zinc oxysulfide, and aluminum oxide.

6. The tandem photovoltaic device of claim 2, wherein the transparent front contact is formed from indium-tin-oxide or aluminum-doped zinc oxide.

7. The tandem photovoltaic device of claim 1, wherein the top cell further comprises:
a bottom electrode;
a hole transporting layer on the bottom electrode, wherein the second absorber layer is present on a side of the hole transporting layer opposite the bottom electrode;
an electron transporting layer on a side of the second absorber layer opposite the hole transporting layer; and
a transparent top electrode on a side of the electron transporting layer opposite the second absorber layer.

8. The tandem photovoltaic device of claim 7, wherein the bottom electrode is formed from indium-tin-oxide or aluminum-doped zinc oxide.

9. The tandem photovoltaic device of claim 7, wherein a transparent front contact of the bottom cell serves as the bottom electrode of the top cell.

10. The tandem photovoltaic device of claim 7, wherein the hole transporting layer comprises poly(3,4-ethylenedioxythiophene)-poly(styrenesulfonate) or molybdenum trioxide.

11. The tandem photovoltaic device of claim 1, wherein the perovskite material has a formula ABX₃, wherein A=CH₃NH₃ or NH═CHNH₃, B=lead or tin, and X=chlorine, bromine, or iodine.

12. The tandem photovoltaic device of claim 7, wherein the electron transporting layer is formed from at least one of phenyl-C61-butyric acid methyl ester, C60, and bathocuproine.

13. The tandem photovoltaic device of claim 7, wherein the transparent top electrode is formed from a metal, indium-tin-oxide, aluminum-doped zinc oxide, or a silver nanowire mesh.

14. A tandem photovoltaic device, comprising:
a substrate;
a layer of electrically conductive material on the substrate;
a first absorber layer on a side of the layer of electrically conductive material opposite the substrate, wherein the first absorber layer comprises copper, zinc, tin, and at least one of sulfur and selenium;
a buffer layer on a side of the first absorber layer opposite the layer of electrically conductive material;
a transparent front contact on a side of the buffer layer opposite the first absorber layer;
a hole transporting layer on a side of the transparent front contact opposite the buffer layer;
a second absorber layer on a side of the hole transporting layer opposite the transparent front contact, wherein the second absorber layer comprises a perovskite material;
an electron transporting layer on a side of the second absorber layer opposite the hole transporting layer; and
a transparent top electrode on a side of the electron transporting layer opposite the second absorber layer.

15. The tandem photovoltaic device of claim 14, wherein the perovskite material has a formula ABX₃, wherein A=CH₃NH₃ or NH═CHNH₃, B=lead or tin, and X=chlorine, bromine, or iodine.

16. A method of forming a tandem photovoltaic device, the method comprising the steps of:
coating a substrate with a layer of electrically conductive material;
forming a first absorber layer on a side of the layer of electrically conductive material opposite the substrate, wherein the first absorber layer comprises copper, zinc, tin, and at least one of sulfur and selenium;
forming a buffer layer on a side of the first absorber layer opposite the layer of electrically conductive material;
forming a transparent front contact on a side of the buffer layer opposite the first absorber layer;
forming a hole transporting layer on a side of the transparent front contact opposite the buffer layer;
forming a second absorber layer on a side of the hole transporting layer opposite the transparent front contact, wherein the second absorber layer comprises a perovskite material;
forming an electron transporting layer on a side of the second absorber layer opposite the hole transporting layer; and
forming a transparent top electrode on a side of the electron transporting layer opposite the second absorber layer.

17. The method of claim 16, further comprising the step of:
varying a ratio of sulfur to selenium in the first absorber layer to vary a band gap of the first absorber layer.

18. The method of claim 16, wherein the step of forming the second absorber layer comprises the step of:
forming the perovskite material from a metal halide and a source of methylammonium halide vapor.

19. The method of claim 18, further comprising the step of:
varying a composition of the metal halide to vary a band gap of the second absorber layer.

20. The method of claim 16, wherein the second absorber layer is formed at a temperature of from about 60° C. to about 150° C., and ranges therebetween.
